(19) United States
(12) Patent Application Publication
(10) Pub. No.: US 2017/0047380 A1
(43) Pub. Date: Feb. 16, 2017

(54) ORGANIC ELECTROLUMINESCENT ELEMENT AND ORGANIC ELECTROLUMINESCENT PANEL

(71) Applicant: Sharp Kabushiki Kaisha, Sakai City, Osaka (JP)

(72) Inventors: Yuto TSUKAMOTO, Sakai City (JP); Katsuhiro KIKUCHI, Sakai City (JP); Hideki UCHIDA, Sakai City (JP); Manabu NIBOSHI, Sakai City (JP); Satoshi INOUE, Sakai City (JP); Yoshiyuki ISOMURA, Sakai City (JP)

(21) Appl. No.: 15/305,362

(22) PCT Filed: Apr. 20, 2015
(86) PCT No.: PCT/JP2015/061935

§ 371 Date: Oct. 20, 2016

(30) Foreign Application Priority Data
Apr. 25, 2014 (JP) 2014-091547

(51) Int. Cl. H01L 27/32; H01L 51/52; H01L 51/50

(52) U.S. Cl. CPC H01L 27/3211; H01L 51/5056; H01L 51/5072; H01L 51/5088; H01L 51/5218; H01L 51/5092

(57) ABSTRACT

An organic electroluminescent element includes, in the following order: an anode; a hole transport layer; a first mixed light-emitting layer; a luminescent dopant layer; a second mixed light-emitting layer; an electron transport layer; and a cathode, the first mixed light-emitting layer containing a first luminescent host material and a first luminescent dopant material, the second mixed light-emitting layer containing a second luminescent host material and a second luminescent dopant material, the luminescent dopant layer consisting essentially only of a third luminescent dopant material and being thinner than the first mixed light-emitting layer and the second mixed light-emitting layer.

### TECHNICAL FIELD

The present invention relates to organic electroluminescent elements (hereinafter, also referred to as “organic EL elements”) and organic electroluminescent panels (hereinafter, also referred to as “organic EL panels”). The present invention more specifically relates to an organic EL element having a configuration suitable for white light emission which utilizes multiple-color light emission, and an organic EL panel including the organic EL element.

### BACKGROUND ART

Organic EL panels have drawn attention which include organic electroluminescent elements utilizing electroluminescence of organic materials (hereinafter, such elements are also referred to as “organic EL elements”). An organic EL element emits light when holes injected from the anode and electrons injected from the cathode recombine in the light-emitting layer disposed between the electrodes. Organic EL panels are superior to liquid crystal display devices when used as display panels for thin display devices in terms of properties such as a high contrast and low power consumption. Organic EL panels are also expected to be developed for use in fields such as illumination lamps as well as display devices.

For illumination lamps, organic EL panels capable of emitting a color of light produced by simply mixing two intermediate colors of light may be enough. However, for display devices for example, organic EL panels emitting a color of light produced by simply mixing two intermediate colors of light may not be able to achieve sufficient color reproducibility of a single color. In order to use organic EL panels for applications such as display devices, an organic EL element structure capable of producing white light has been strongly desired. Various organic EL element structures capable of producing white light have been developed. For example, an element structure called a tandem element structure is known which includes vertically stacked organic EL elements and is driven by a single power source. A typical tandem structure includes organic EL elements each emitting light having a primary color, but a tandem structure including a stack of organic EL elements emitting white light is also known as disclosed in, for example, Patent Literature 1.

Other known element structures include an element structure in which light-emitting layers of multiple colors are stacked side by side (e.g. Patent Literatures 2, 3) and an element structure in which a single light-emitting layer contains two or more luminescent dopant materials with different peak emission wavelengths (e.g. Patent Literature 4).

### CITATION LIST

### Patent Literature

### Patent Literature 1: JP 2008-511100 T

### Patent Literature 2: JP 2009-532825 T

### Patent Literature 3: JP 2013-125653 A

### Patent Literature 4: JP 2011-228569 A

### SUMMARY OF INVENTION

### Technical Problem

FIG. 6 is a schematic cross-sectional view illustrating one example of an organic EL panel having a conventional tandem structure. In an organic EL panel 200A illustrated in FIG. 6, an organic EL element 220A disposed on a substrate 210 has a structure in which an anode 222, a first hole injection layer 223, a blue light-emitting layer 226B, a first electron injection layer 229, an intermediate layer 231, a second hole injection layer 223, a yellow light-emitting layer 226Y, a second electron injection layer 229, and a cathode 230 are stacked in the given order from the substrate 210 side. A hole transport layer may be disposed between the first hole injection layer 223 and the blue light-emitting layer 226B and between the second hole injection layer 223 and the yellow light-emitting layer 226Y. An electron transport layer may be disposed between the blue light-emitting layer 226B and the first electron injection layer 229 and between the yellow light-emitting layer 226Y and the second electron injection layer 229.

In the organic EL element 220A having the tandem structure described above, the light-emission positions are completely vertically separated by the intermediate layer 231. This structure may enable easy carrier balance but bring difficulties in selecting a material suitable for the intermediate layer 231 configured to transfer holes and electrons. Such a structure therefore has problems of a high drive voltage and a decrease in the luminous efficacy due to carrier loss in the intermediate layer, for example. In addition, this structure provides low productivity as it requires two to three times as many layers as required in the later-described element structure illustrated in FIG. 7.

FIG. 7 is a schematic cross-sectional view illustrating one example of an organic EL panel having a conventional element structure in which light-emitting layers of multiple colors are stacked. In an organic EL panel 200B illustrated in FIG. 7, an organic EL element 220B disposed on the substrate 210 has a structure in which the anode 222, the hole injection layer 223, the blue light-emitting layer 226B, a red light-emitting layer 226R, a green light-emitting layer 226G, the electron injection layer 229, and the cathode 230 are stacked in the given order from the substrate 210 side. A hole transport layer may be disposed between the hole injection layer 223 and the blue light-emitting layer 226B. An electron transport layer may be disposed between the green light-emitting layer 226G and the electron injection layer 229.

The organic EL element 220B illustrated in FIG. 7 unfortunately has low luminous efficacy as it is difficult to achieve efficient light emission of the luminescent materials having the respective colors in all the three layers of the blue light-emitting layer 226B, the red light-emitting layer 226R, and the green light-emitting layer 226G by controlling the light-emission positions. That is, although conventional element structures in which light-emitting layers of multiple colors are stacked can achieve efficient two-color light emission by a technique of, for example, concentrating carriers at the interface between the two light-emitting layers, it has been technically difficult for these structures to achieve efficient three-color light emission required for white light emission.

As to the element structure including a single light-emitting layer that contains two or more luminescent dopant materials, since this structure is formed through co-deposition of multiple luminescent dopant materials, the structure may possibly fail to practically emit colors of light other than single colors of light when energy transfer occurs between the luminescent dopant materials.

Conventional element structures can therefore still be improved to be applied to applications which require white light emission, such as displays.

The present invention has been made in view of such a current state of the art, and aims to provide an organic electroluminescent element capable of achieving high productivity and white light emission with high luminous efficacy, and an organic electroluminescent panel including the organic electroluminescent element.

### Solution to Problem

The inventors have made various studies on organic EL elements having a relatively simple structure and achieving white light emission with high luminous efficacy. As a result, the inventors have found that with a light-emitting unit having a configuration that includes a stack of mixed light-emitting layers containing a luminescent host material and a luminescent dopant material and a luminescent dopant layer consisting essentially only of a luminescent dopant material and being thinner than the mixed light-emitting layers, a carrier recombination region can be expanded to the entire light-emitting unit and advantages in white light emission can be achieved. The inventors have then found that the above problems can be solved by optimizing the configuration of the light-emitting unit, and thereby completed the present invention.

That is, one aspect of the present invention may be an organic electroluminescent element including, in the following order: an anode; a hole transport layer; a first mixed light-emitting layer; a luminescent dopant layer; a second mixed light-emitting layer; an electron transport layer; and a cathode, the first mixed light-emitting layer containing a first luminescent host material and a first luminescent dopant material, the second mixed light-emitting layer containing a second luminescent host material and a second luminescent dopant material, the luminescent dopant layer consisting essentially only of a third luminescent dopant material and being thinner than the first mixed light-emitting layer and the second mixed light-emitting layer.

Another aspect of the present invention may be an organic electroluminescent panel including: a substrate; and the above-described organic electroluminescent element disposed on the substrate.

### Advantageous Effects of Invention

The organic EL element of the present invention includes a thin film of a luminescent dopant layer consisting essentially only of a luminescent dopant material between the first and second mixed light-emitting layers that contain a luminescent host material and a luminescent dopant material. The organic EL element can thereby inhibit formation of barriers for carriers at the interfaces between the layers compared with a configuration including a stack of mixed light-emitting layers. The organic EL element can also include a thinner carrier recombination region. Such an organic EL element, even in the case of achieving white light emission, can achieve efficient light emission of the luminescent dopant materials in the mixed light-emitting layers and the luminescent dopant layer, thereby achieving high luminous efficacy.

Furthermore, the luminescent dopant layer can be formed by vapor deposition of a luminescent dopant material alone in a short time, for example. The organic EL element of the present invention therefore achieves higher productivity than those having a conventional configuration including a stack of mixed light-emitting layers.

The organic EL panel of the present invention also includes an organic EL element achieving both high luminous efficacy and high productivity. Thus, the organic EL panel enables a display device, an illumination lamp, or the like product that achieves high productivity, low power consumption, and high luminance.

### BRIEF DESCRIPTION OF DRAWINGS

FIG. 1 is a schematic cross-sectional view of an organic EL panel of Example 1.

FIG. 2 is a schematic cross-sectional view of an organic EL panel of Example 2.

FIG. 3 is a schematic cross-sectional view of an organic EL panel of Example 3.

FIG. 4 is a schematic cross-sectional view of an organic EL panel of Example 4.

FIG. 5 is a schematic cross-sectional view of an organic EL panel of Example 5.

FIG. 6 is a schematic cross-sectional view illustrating one example of an organic EL panel having a conventional tandem structure.

FIG. 7 is a schematic cross-sectional view illustrating one example of an organic EL panel having a conventional element structure in which light-emitting layers of multiple colors are stacked.

### DESCRIPTION OF EMBODIMENTS

The organic electroluminescence herein is also referred to as “organic EL”. The organic EL element is what is generally called an organic light emitting diode (OLED).

The following examples illustrate the present invention in more detail referring to the drawings. The examples, however, are not meant to limit the scope of the present invention. The configurations in the examples may appropriately be combined or modified within the spirit of the present invention.

### Example 1

An organic EL panel of Example 1 includes organic EL elements each having the following configuration.

That is, the organic EL elements of Example 1 each include an anode, a hole transport layer, a first mixed light-emitting layer, a luminescent dopant layer, a second mixed light-emitting layer, an electron transport layer, and a cathode in the given order. The first mixed light-emitting layer contains a first luminescent host material and a first luminescent dopant material. The second mixed light-emitting layer contains a second luminescent host material and a second luminescent dopant material. The luminescent dopant layer consists essentially only of a third luminescent dopant material, and is thinner than the first mixed light-emitting layer and the second mixed light-emitting layer.

The organic EL panel of Example 1 has a feature of including a substrate and the organic EL elements disposed on the substrate.

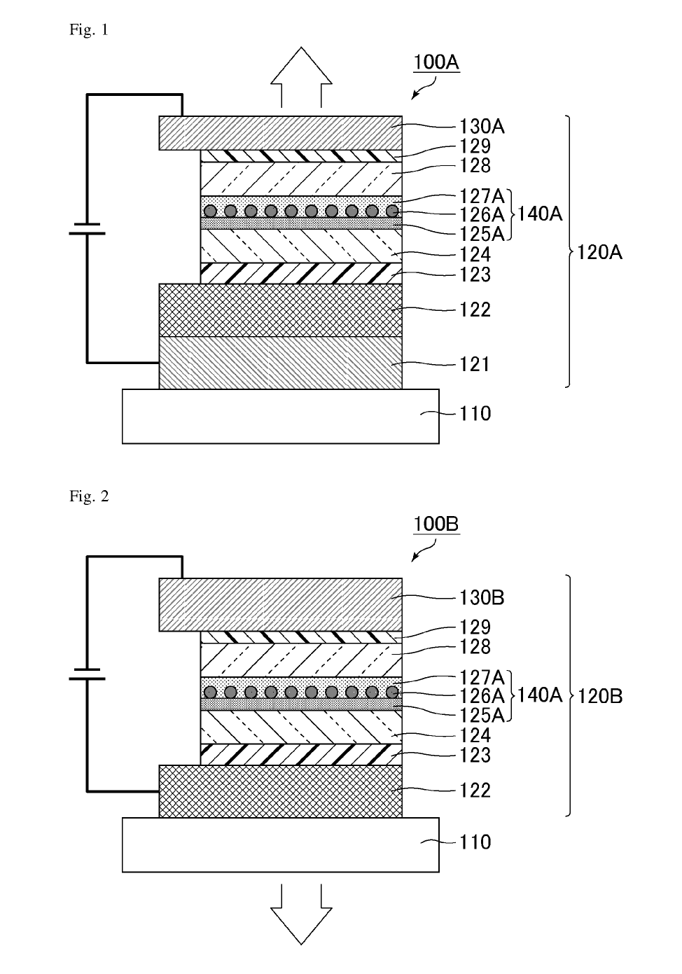

Hereinafter, the organic EL panel of the present example is described in detail referring to FIG. 1.

FIG. 1 is a schematic cross-sectional view of an organic EL panel of Example 1. In an organic EL panel 100A illustrated in FIG. 1, organic EL elements 120A disposed on a substrate 110 each have a structure in which a reflective electrode 121, an anode 122, a hole injection layer 123, a hole transport layer 124, a first mixed light-emitting layer 125A, a luminescent dopant layer 126A, a second mixed light-emitting layer 127A, an electron transport layer 128, an electron injection layer 129, and a cathode 130A are stacked in the given order from the substrate 110 side. In the organic EL element 120A, the first mixed light-emitting layer 125A, the luminescent dopant layer 126A, and the second mixed light-emitting layer 127A constitute a light-emitting unit 140A, and an intermediate layer used in a tandem structure is not included.

The substrate 110 can be a glass substrate or a plastic substrate, for example. Use of a bendable plastic substrate as the substrate 110 enables production of a flexible organic EL panel. Although not illustrated in FIG. 1, thin-film transistors are disposed on the substrate 110. The driving of the organic EL elements 120A can be controlled by electrically connecting the thin-film transistors to the respective reflective electrodes 121.

In the organic EL panel 100A of the present example, the reflective electrode 121 disposed under the anode 122 has light reflectivity and the cathode 130A, which is transparent, has light transmissivity. That is, the organic EL element 120A of the present example is a top-emission element that emits light from the cathode 130A side. The arrow illustrated in FIG. 1 indicates the direction in which light emitted from the organic EL element 120A travels.

The reflective electrode 121 was made of silver (Ag). The reflective electrode 121 can be an electrode having light reflectivity, and may alternatively be an aluminum (Al) layer or an indium (In) layer, for example. The reflective electrode 121 had a thickness of 100 nm.

The anode 122 was made of indium tin oxide (ITO). The anode 122 had a thickness of 50 nm.

In the case of using the organic EL panel for color displays, for example, patterning the anodes 122 to give different thicknesses to the anodes 122 correspondingly to different pixels produces different light interferences in different pixels, so that different colors of light can be produced in different pixels. Such a design can achieve a display capable of providing both single-color display and white-color display. For example, the anodes 122 may have a thickness of 20 nm in blue pixels, 60 nm in green pixels, and 100 nm in red pixels.

The hole injection layer 123 used was dipyrazino[2,3-f:2′,3′-h]quinoxaline-2,3,6,7,10,11-hexacarbonitrile (HAT-CN). The hole injection layer 123 may be made of the same material as the hole injection material used for a typical organic EL element. The hole injection layer 123 had a thickness of 10 nm.

The hole transport layer 124 was made of 4,4′-bis[N-(1-naphthyl)-N-phenyl-amino]-biphenyl (α-NPD). The α-NPD has a hole mobility μₕ of 10⁻³ to 10⁻⁴ cm²/Vsec. The hole transport layer 124 can be made of the same material as the hole transport material used for a typical organic EL element. The hole transport layer 124 had a thickness of 20 nm.

The first mixed light-emitting layer 125A contains at least one luminescent host material (first luminescent host material) and at least one luminescent dopant material (first luminescent dopant material). Herein, a light-emitting layer containing both a luminescent host material and a luminescent dopant material is referred to as a “mixed light-emitting layer”. The present example utilized a mixed light-emitting layer containing 2,2′,2″-(1,3,5-benzinetriyl)-tris(1-phenyl-1-H-benzimidazole (TPBI) having a high electron mobility as the first luminescent host material and [bis(3,5-difluoro-2-(2-pyridylphenyl-(2-carboxypyridyl)iridium(III)] (FIrpic) as the first luminescent dopant material. The ratio by weight of TPBI to FIrpic was 0.9:0.1. TPBI has an electron mobility μₑ of about 10⁻⁵ to 10⁻⁶ cm²/Vsec.

The first luminescent host material preferably has high electron transportability and bipolarity. In the first luminescent host material, the electron mobility μₑ is preferably higher than the hole mobility μₕ, and the hole mobility μₕ and the electron mobility μₑ more preferably satisfy the relation of 1<μₑ/μₕ<1000. For example, in the case that the first luminescent host material consists of multiple luminescent host materials, the highest hole mobility μₕ among the hole mobilities μₕ and the highest electron mobility μₑ among the electron mobilities μₑ of the respective luminescent host materials preferably satisfy the above relation. More preferably, the highest hole mobility μₕ₁ and the highest electron mobility μₑ₁ among all the materials contained in the first mixed light-emitting layer 125A satisfy the relation of 1<μₑ₁/μₕ₁<1000. The hole mobility μₕ and the electron mobility μₑ can be determined by the time-of-flight method, for example. Specifically, the values can be measured with a measurement device such as a photoexcited carrier mobility measurement system (Sumitomo Heavy Industries, Ltd., trade name: TOF-401). The first luminescent host material may be a mixture of an electron transportable material and a hole transportable material.

The first luminescent dopant material can be a fluorescent dopant material or a phosphorescent dopant material.

The first mixed light-emitting layer 125A had a thickness of 5 nm. The lower limit of the thickness of the first mixed light-emitting layer 125A is preferably 2 nm, while the upper limit thereof is preferably 10 nm, more preferably 5 nm.

The first mixed light-emitting layer 125A can be formed by, for example, vapor co-deposition of the first luminescent host material and the first luminescent dopant material.

The luminescent dopant layer 126A consists essentially only of a luminescent dopant material (third luminescent dopant material). That is, the concentration of the third luminescent dopant material in the luminescent dopant layer 126A is 100 wt % or substantially 100 wt %. Here, the expression “the concentration of the luminescent dopant material in the luminescent dopant layer is substantially 100 wt %” means that the luminescent dopant layer containing the luminescent dopant material does not contain any other material affecting the properties of the luminescent dopant layer. The luminescent dopant layer may contain a trace of impurities as well as the luminescent dopant material, but the amount is preferably up to less than 3 wt %.

The third luminescent dopant material can be a fluorescent dopant material or a phosphorescent dopant material. The present example utilized tris-(picolinate)iridium (Ir(pic)3) as the third luminescent dopant material. The third luminescent dopant material may consist of a single or multiple luminescent dopant materials, but preferably consists of a single luminescent dopant material.

The luminescent dopant layer 126A is thinner than the first and second mixed light-emitting layers 125A and 127A and has an island shape. That is, the luminescent dopant layer 126A includes a portion where the hole transport layer 124 and the luminescent dopant layer 126A are in direct contact with each other. The luminescent dopant layer 126A can be formed in an island shape simply by shortening the vapor deposition time. Specifically, when an ultrathin film having a maximum thickness of 1 nm or smaller is formed by vapor deposition, the resulting film has an island shape. The luminescent dopant layer 126A had a thickness of 0.2 nm at its thickest part (the maximum thickness). The lower limit of the maximum thickness of the luminescent dopant layer 126A is preferably 0.1 nm, while the upper limit thereof is preferably 1 nm, more preferably 0.5 nm.

The luminescent dopant layer 126A can be formed by vapor deposition of a third luminescent dopant material.

Forming the luminescent dopant layer 126A in an island shape with a concentration of the third luminescent dopant material of 100 wt % or substantially 100 wt % can prevent defects such as (1) a decrease in luminous efficacy due to concentration quenching and (2) an increase in drive voltage and a decrease in luminous efficacy due to disrupted carrier transportation.

The second mixed light-emitting layer 127A contains at least one luminescent host material (second luminescent host material) and at least one luminescent dopant material (second luminescent dopant material). The present example utilized a mixed layer containing 4,4′,4″-tris(carbazol-9-yl)-triphenylamine (TCTA) having a high hole mobility as the second luminescent host material and tris(2-phenylpyridinato)iridium(III) (Ir(ppy)3) as the second luminescent dopant material. The ratio by weight of TCTA to Ir(ppy)3 was 0.9:0.1.

The second luminescent host material preferably has high hole transportability and bipolarity. In the second luminescent host material, the hole mobility μₕ is preferably higher than the electron mobility μₑ, and the hole mobility μₕ and the electron mobility μₑ more preferably satisfy the relation of 1<μₕ/μₑ<1000. For example, in the case that the second luminescent host material consists of multiple luminescent host materials, the highest hole mobility μₕ among the hole mobilities μₕ and the highest electron mobility μₑ among the electron mobilities μₑ of the respective luminescent host materials preferably satisfy the above relation. More preferably, the highest hole mobility μₕ₂ and the highest electron mobility μₑ₂ among all the materials contained in the second mixed light-emitting layer 127A satisfy the relation of 1<μₕ₂/μₑ₂<1000. The second luminescent host material may be a mixture of an electron transportable material and a hole transportable material.

The second luminescent dopant material can be a fluorescent dopant material or a phosphorescent dopant material.

The second mixed light-emitting layer 127A had a thickness of 5 nm. The lower limit of the thickness of the second mixed light-emitting layer 127A is preferably 2 nm, while the upper limit thereof is preferably 10 nm, more preferably 5 nm.

The second mixed light-emitting layer 127A can be formed by, for example, vapor co-deposition of the second luminescent host material and the second luminescent dopant material.

The first, second, and third luminescent dopant materials are preferably selected to respectively enable the first mixed light-emitting layer 125A, luminescent dopant layer 126A, and second mixed light-emitting layer 127A to emit the respective different three primary colors of light, and may be in any combination.

The third luminescent dopant material contained in the luminescent dopant layer 126A preferably has a photoluminescence (PL) peak at a longer wavelength than the first and second luminescent dopant materials respectively contained in the first and second mixed light-emitting layers 125A and 127A. Hence, preferably, in the case of utilizing three-primary-color emission, the first and second luminescent dopant materials are materials emitting blue light and green light, and the third luminescent dopant material is a material emitting red light.

The electron transport layer 128 was made of bathophenanthroline (Bphen). The electron transport layer 128 can be made of the same material as the electron transport material used for a typical organic EL element. Bphen has an electron mobility μₑ of 10⁻⁴ to 10⁻⁵ cm²/Vsec. The electron transport layer 128 had a thickness of 30 nm.

The electron injection layer 129 was made of lithium fluoride (LiF). The electron injection layer 129 can be made of the same material as the electron injection material used for a typical organic EL element. The electron injection layer 129 had a thickness of 1 nm.

The cathode 130A was a layer containing Ag and magnesium (Mg). The content ratio by weight of Ag to Mg was 0.9:0.1. The cathode 130A can be made of a light-transparent, electrically conductive material such as ITO or indium zinc oxide (IZO) in place of the above materials. The cathode 130A had a thickness of 20 nm.

In the present example, the light-emitting unit 140A has the following features.

(1) The light-emitting unit 140A has a stacking structure in which the first mixed light-emitting layer 125A, the luminescent dopant layer 126A, and the second mixed light-emitting layer 127A are stacked in the given order. The configuration of this stacking structure is simplified without an intermediate layer used in a tandem structure, and enables formation of the layers by vapor deposition. This configuration therefore achieves high productivity. Also, since the luminescent dopant layer 126A which is an island-shaped ultrathin film is used, the light-emitting unit 140A has a small thickness and does not include a barrier for carriers at the interface between layers containing the luminescent host material, compared with a conventional light-emitting unit in which three mixed light-emitting layers are stacked. Hence, this structure is likely to enable carriers to spread to the entire light-emitting unit 140A, and utilizes all the three layers as the carrier recombination regions to achieve efficient light emission by all the three luminescent dopant materials, thereby achieving high luminous efficacy. As described above, the light-emitting unit 140A can achieve white light emission with high luminous efficacy, though having a simple structure without an intermediate layer.

(2) In a preferred embodiment, the first mixed light-emitting layer 125A on the anode 122 side contains a first luminescent host material having high electron transportability, and the second mixed light-emitting layer 127A on the cathode 130A side contains a second luminescent host material having high hole transportability. This structure enables easy spread of carriers, achieving efficient light emission by the stacked three layers, namely the first mixed light-emitting layer 125A, the luminescent dopant layer 126A, and the second mixed light-emitting layer 127A.

(3) In a preferred embodiment, the third luminescent dopant material constituting the luminescent dopant layer 126A has a PL peak at a longer wavelength than the first and second luminescent dopant materials. When the carriers are allowed to spread easily as described in the above feature (2), the luminescent dopant layer 126A disposed between the first mixed light-emitting layer 125A and the second mixed light-emitting layer 127A is less likely to emit light than the other layers. In contrast, when the third luminescent dopant material having a PL peak at the longest wavelength among the luminescent dopant materials is disposed at the center, energy transfer from the first and second luminescent dopant materials to the third luminescent dopant material is more likely to occur, so that the luminescent dopant layer 126A can emit light efficiently. This structure therefore enables the three layers to emit light in a good balance, achieving white light emission.

### Example 2

Although Example 1 relates to a top-emission organic EL panel, the configuration of the present invention can also be applied to a bottom-emission organic EL panel. Example 2 relates to a bottom-emission organic EL panel, and is the same as Example 1 except for a pair of electrodes.

FIG. 2 is a schematic cross-sectional view of an organic EL panel of Example 2. In an organic EL panel 100B illustrated in FIG. 2, an organic EL element 120B disposed on the substrate 110 has a structure in which the anode 122, the hole injection layer 123, the hole transport layer 124, the first mixed light-emitting layer 125A, the luminescent dopant layer 126A, the second mixed light-emitting layer 127A, the electron transport layer 128, the electron injection layer 129, and a cathode 130B are stacked in the given order from the substrate 110 side. The arrow in FIG. 2 indicates the direction in which light emitted from the organic EL element 120B travels.

In the present example, the anode 122 was made of ITO. The anode 122 had a thickness of 100 nm.

In the present example, the cathode 130B was made of aluminum (Al). The cathode 130B had a thickness of 100 nm.

The present example, similarly to Example 1, can also provide a device capable of providing white display by achieving efficient light emission by all the three luminescent dopant materials.

### Example 3

In Example 1, TPBI having a high electron mobility was used as the first luminescent host material in the first mixed light-emitting layer 125A, and TCTA having a high hole mobility was used as the second luminescent host material in the second mixed light-emitting layer 127A. In the present invention, however, the first and second mixed light-emitting layers may each contain two or more luminescent host materials. With a material having a high hole mobility and a material having a high electron mobility mixed in an appropriate ratio, the transportability of each of the first and second mixed light-emitting layers can be controlled. Thereby, the balance between the luminous efficacies of the respective colors can be controlled.

Example 3 relates to an organic EL panel in which the first and second luminescent host materials each are a mixture of TCTA having a high hole mobility and TPBI having a high electron mobility mixed in a predetermined ratio. Example 3 is the same as Example 1 except for the first and second luminescent host materials.

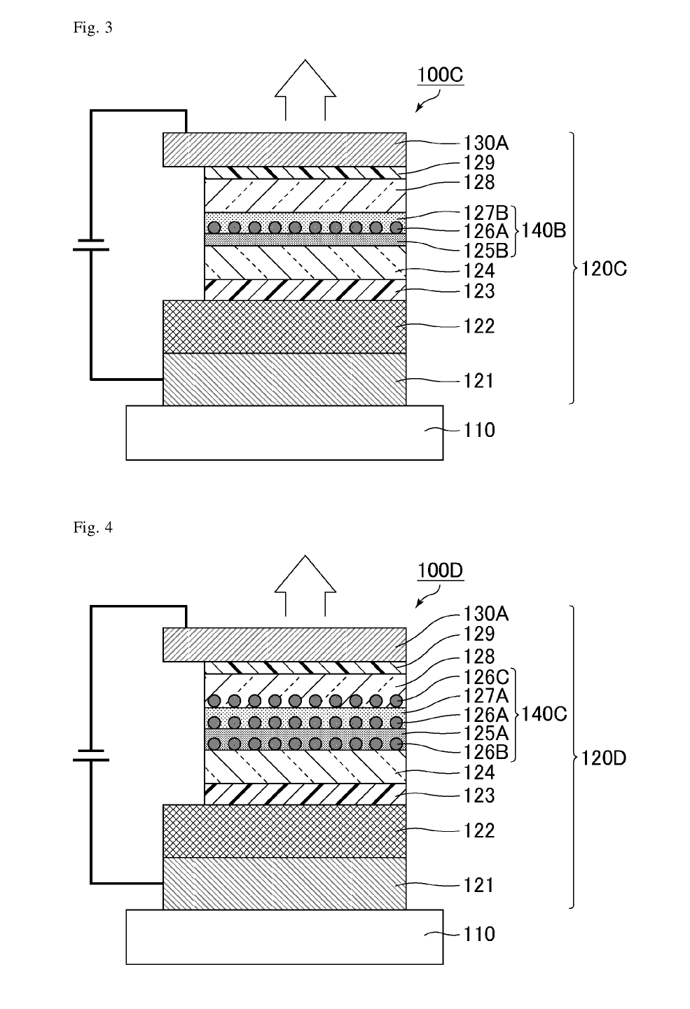

FIG. 3 is a schematic cross-sectional view of an organic EL panel of Example 3. In an organic EL panel 100C illustrated in FIG. 3, an organic EL element 120C disposed on the substrate 110 has a structure in which the reflective electrode 121, the anode 122, the hole injection layer 123, the hole transport layer 124, a first mixed light-emitting layer 125B, the luminescent dopant layer 126A, a second mixed light-emitting layer 127B, the electron transport layer 128, the electron injection layer 129, and the cathode 130A are stacked in the given order from the substrate 110 side. The first mixed light-emitting layer 125B, the luminescent dopant layer 126A, and the second mixed light-emitting layer 127B constitute a light-emitting unit 140B. The arrow in FIG. 3 indicates the direction in which light emitted from the organic EL element travels.

The first mixed light-emitting layer 125B was a mixed light-emitting layer containing TCTA having a high hole mobility and TPBI having a high electron mobility as the first luminescent host materials, and FIrpic as the first luminescent dopant material. The ratio by weight of TCTA, TPBI, and FIrpic was 0.7:0.2:0.1. The first mixed light-emitting layer 125B had a thickness of 5 nm.

The second mixed light-emitting layer 127B was a mixture layer containing TCTA having a high hole mobility and TPBI having a high electron mobility as the first luminescent host materials, and Ir(ppy)3 as the first luminescent dopant material. The ratio by weight of TCTA, TPBI, and FIrpic was 0.2:0.7:0.1. The second mixed light-emitting layer 127B had a thickness of 5 nm.

The present example, similarly to Example 1, can also provide a device capable of providing white display by achieving efficient light emission by all the three luminescent dopant materials. Also, with the first and second mixed light-emitting layers 125B and 127B having higher bipolarity, the device may be able to achieve even higher efficiency.

### Example 4

In a configuration in which a luminescent dopant layer is disposed between the first and second mixed light-emitting layers, very strong energy transfer to the third luminescent dopant material in the luminescent dopant layer disables the first and second luminescent dopant materials in the first and second mixed light-emitting layers from emitting light sufficiently. In contrast, by additionally disposing luminescent dopant layer(s) (first and/or second auxiliary dopant layer(s)) on the anode 122 side of the first mixed light-emitting layer and/or the cathode side of the second mixed light-emitting layer, the luminous efficacies of the first and second luminescent dopant materials can be increased.

Example 4 relates to an organic EL panel including a light-emitting unit in which a first auxiliary dopant layer, a first mixed light-emitting layer, a luminescent dopant layer, a second mixed light-emitting layer, and a second auxiliary dopant layer were stacked in the given order. Example 4 is the same as Example 1 except for the light-emitting unit.

FIG. 4 is a schematic cross-sectional view of an organic EL panel of Example 4. In an organic EL panel 100D illustrated in FIG. 4, an organic EL element 120D disposed on the substrate 110 has a structure in which the reflective electrode 121, the anode 122, the hole injection layer 123, the hole transport layer 124, a first auxiliary dopant layer 126B, the first mixed light-emitting layer 125A, the luminescent dopant layer 126A, the second mixed light-emitting layer 127A, a second auxiliary dopant layer 126C, the electron transport layer 128, the electron injection layer 129, and the cathode 130A are stacked in the given order from the substrate 110 side. The first auxiliary dopant layer 126B, the first mixed light-emitting layer 125A, the luminescent dopant layer 126A, the second mixed light-emitting layer 127A, and the second auxiliary dopant layer 126C constitute a light-emitting unit 140C. The arrow in FIG. 4 indicates the direction in which light emitted from the organic EL element 120D travels.

The first auxiliary dopant layer 126B consists essentially only of a luminescent dopant material (fourth luminescent dopant material), and the fourth luminescent dopant material used was FIrpic. Since the fourth luminescent dopant material is used to support luminescence of the first luminescent dopant material, the fourth luminescent dopant material preferably has a light emission spectrum whose peak emission wavelength is within 20 nm from the peak emission wavelength of the first luminescent dopant material. In the present example, the same material as the first luminescent dopant material was used.

The first auxiliary dopant layer 126B is formed in an island shape, and had a thickness of 0.2 nm at its thickest part (maximum thickness). The lower limit of the maximum thickness of the first auxiliary dopant layer 126B is preferably 0.1 nm, while the upper limit is preferably 1 nm, more preferably 0.5 nm.

The second auxiliary dopant layer 126C consists essentially only of a luminescent dopant material (fifth luminescent dopant material), and the fifth luminescent dopant material used was Ir(ppy)3. Since the fifth luminescent dopant material is used to support luminescence of the second luminescent dopant material, the fifth luminescent dopant material preferably has a light emission spectrum whose peak emission wavelength is within 20 nm from the peak emission wavelength of the second luminescent dopant material. In the present example, the same material as the second luminescent dopant material was used.

The second auxiliary dopant layer 126C is formed in an island shape, and had a thickness of 0.2 nm at its thickest part (maximum thickness). The lower limit of the maximum thickness of the second auxiliary dopant layer 126C is preferably 0.1 nm, while the upper limit is preferably 1 nm, more preferably 0.5 nm.

Since the first and second auxiliary dopant layers 126B and 126C are separated from and do not come into direct contact with the luminescent dopant layer 126A, energy transfer to the third luminescent dopant material tends not to occur. Hence, when the first and second auxiliary dopant layers 126B and 126C are disposed, the luminous efficacies of the first and second luminescent dopant materials can be increased compared with the case where the luminescent dopant layer 126A is disposed only between the first mixed light-emitting layer 125A and the second mixed light-emitting layer 127A as in Example 1.

The present example can also provide a device capable of providing white display by achieving efficient light emission by all the three luminescent dopant materials.

### Example 5

In the case that excessive energy transfer occurs from the first luminescent dopant material in the first mixed light-emitting layer and/or the second luminescent dopant material in the second mixed light-emitting layer to the third luminescent dopant material in the luminescent dopant layer, a block layer may be disposed between the first mixed light-emitting layer and the luminescent dopant layer and/or between the luminescent dopant layer and the second mixed light-emitting layer. This structure can increase the luminous efficacy of the luminescent dopant materials in the mixed light-emitting layers separated by the block layer from the luminescent dopant layer. For example, if luminescence of the first luminescent dopant material in the first mixed light-emitting layer is insufficient, a thin film made of the first luminescent host material contained in the first mixed light-emitting layer can be utilized as the block layer.

Example 5 relates to an organic EL panel in which a block layer (organic layer) containing the first luminescent host material is inserted between the first mixed light-emitting layer and the luminescent dopant layer. Example 5 is the same as Example 1 except for the insertion of the block layer.

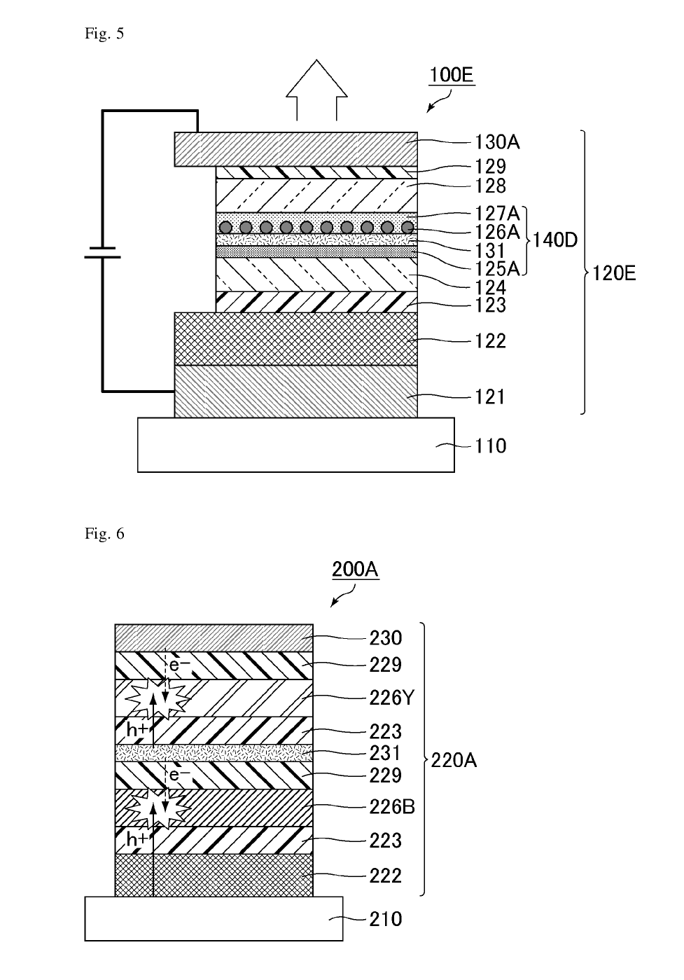

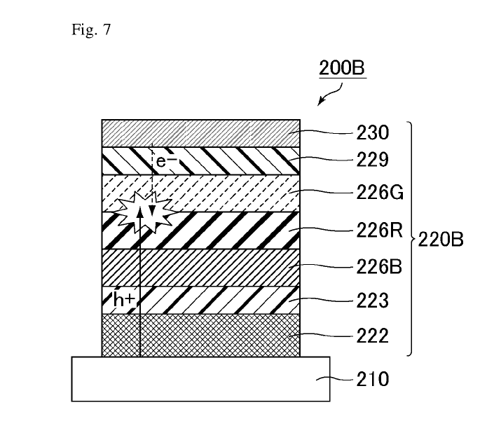

FIG. 5 is a schematic cross-sectional view of an organic EL panel of Example 5. In an organic EL panel 100E illustrated in FIG. 5, an organic EL element 120E disposed on the substrate 110 has a structure in which the reflective electrode 121, the anode 122, the hole injection layer 123, the hole transport layer 124, the first mixed light-emitting layer 125A, a block layer (organic layer) 131, the luminescent dopant layer 126A, the second mixed light-emitting layer 127A, the electron transport layer 128, the electron injection layer 129, and the cathode 130A are stacked in the given order from the substrate 110 side. The first mixed light-emitting layer 125A, the block layer 131, the luminescent dopant layer 126A, and the second mixed light-emitting layer 127A constitute a light-emitting unit 140D. The arrow in FIG. 5 indicates the direction in which light emitted from the organic EL element 120E travels.

The block layer 131 can be made of any of various organic materials. Still, the block layer 131 is preferably made of a bipolar material capable of transporting both carriers of electrons and holes, and examples thereof include hole transport materials such as TPD and TCTA and electron transport materials such as Alq3 and BCP. A suitable material is a luminescent host material because of its tendency of causing energy transfer to luminescent dopant materials. Examples of the luminescent host material of the block layer 131 include the first luminescent host material contained in the first mixed light-emitting layer 125A, the second luminescent host material contained in the second mixed light-emitting layer 127A, a luminescent host material not contained in the first and second mixed light-emitting layers 125A and 127A, and a combination of these materials. The present example utilized TPBI, which corresponds to the first luminescent host material, as the material of the block layer 131.

The material of the block layer 131 preferably has a hole mobility μₕ₃ and an electron mobility μₑ₃ that preferably satisfy the relation of 0.01<μₑ₃/μₕ₃<100, more preferably 0.1<μₑ₃/μₕ₃<10. For example, in the case that the block layer 131 contains both the first and second luminescent host materials, the highest hole mobility μₕ₃ among the hole mobilities μₕ₃ and the highest electron mobility μₑ₃ among the electron mobilities μₑ₃ of the respective first and second luminescent host materials preferably satisfy the above relation. In the case that the block layer 131 consists only of the first luminescent host material, more suitable as the first luminescent host material is a material whose hole mobility μₕ₃ and electron mobility μₑ₃ satisfy the relation of 0.01<μₑ₃/μₕ₃<100, more preferably 0.1<μₑ₃/μₕ₃<10.

The block layer 131 had a thickness of 5 nm. The lower limit of the thickness of the block layer 131 is preferably 2 nm, while the upper limit thereof is preferably 10 nm, more preferably 5 nm.

The present example can also provide a device capable of providing white display by achieving efficient light emission by all the three luminescent dopant materials.

The organic EL panel 100E of Example 5 may be modified to have a configuration in which the block layer 131 is disposed between the luminescent dopant layer 126A and the second mixed light-emitting layer 127A. When the block layer 131 is disposed both between the first mixed light-emitting layer 125A and the luminescent dopant layer 126A and between the luminescent dopant layer 126A and the second mixed light-emitting layer 127A, the energy transfer to the third luminescent dopant material in the luminescent dopant layer 126A is excessively suppressed. Hence, the block layer 131 is preferably disposed at either one of these positions. That is, the luminescent dopant layer 126A is preferably in direct contact with at least one of the first mixed light-emitting layer 125A and the second mixed light-emitting layer 127A.

### ADDITIONAL REMARKS

Hereinafter, preferred modes of the organic EL element of the present invention are described. The modes may be appropriately combined within the spirit of the present invention.

The luminescent dopant layer may have a thickness of 1 nm or smaller. This mode enables the luminescent dopant layer to be formed in an island shape and enables the carriers to spread to the entire light-emitting unit, thereby achieving efficient light emission.

The highest hole mobility Phi and the highest electron mobility μₑ₁ among all the materials contained in the first mixed light-emitting layer may satisfy the relation of 1<μₑ₁/μₕ₁<1000. Since the carriers can spread easily when the electron transportability of the first mixed light-emitting layer is increased in this manner, this mode can achieve even higher efficiency.

The highest hole mobility μₕ₂ and the highest electron mobility μₑ₂ among all the materials contained in the second mixed light-emitting layer may satisfy the relation of 1<μₕ₂/μₑ₂<1000. Since the carriers can spread easily when the hole transportability of the second mixed light-emitting layer is increased in this manner, this mode can achieve even higher efficiency.

The third luminescent dopant material may have a peak emission at a longer wavelength than the first luminescent dopant material and the second luminescent dopant material. When the third luminescent dopant material having a peak emission at the longest wavelength among the luminescent dopant materials is disposed at the center, energy transfer from the first and second luminescent dopant materials to the third luminescent dopant material is more likely to occur, so that the luminescent dopant layer can emit light efficiently. This structure therefore enables the stacked three layers, namely the first mixed light-emitting layer, the luminescent dopant layer, and the second mixed light-emitting layer, to emit light in a good balance, achieving white light emission.

The organic EL element of the present invention may further include at least one of a first auxiliary dopant layer that is disposed between the hole transport layer and the first mixed light-emitting layer and is consisting essentially only of a fourth luminescent dopant material, and a second auxiliary dopant layer that is disposed between the second mixed light-emitting layer and the electron transport layer and is consisting essentially only of a fifth luminescent dopant material. Since the first and second auxiliary dopant layers are separated from and do not come into direct contact with the luminescent dopant layer, energy transfer to the third luminescent dopant material tends not to occur. Hence, when the first and second auxiliary dopant layers are disposed, the luminous efficacies of the first and second luminescent dopant materials can be increased.

The first auxiliary dopant layer or second auxiliary dopant layer may have a thickness of 1 nm or smaller. This mode enables the first or second auxiliary dopant layer to be formed in an island shape and enables the carriers to spread to the entire light-emitting unit, thereby achieving efficient light emission.

The fourth luminescent dopant material may have a light emission spectrum whose peak emission wavelength is within 20 nm from the peak emission wavelength of the first luminescent dopant material, and the fifth luminescent dopant material may have a light emission spectrum whose peak emission wavelength is within 20 nm from the peak emission wavelength of the second luminescent dopant material. This mode enables the fourth luminescent dopant material to support luminescence of the first luminescent dopant material and enables the fifth luminescent dopant material to support luminescence of the second luminescent dopant material.

The organic EL element of the present invention may further include an organic layer (block layer) disposed between the first mixed light-emitting layer and the luminescent dopant layer or between the luminescent dopant layer and the second mixed light-emitting layer. This mode suppresses energy transfer between the dopants, and thereby prevents a decrease in the luminous efficacy.

The organic layer may have a thickness of 10 nm or smaller. This mode enables carriers to spread to the entire light-emitting unit even in the presence of an organic layer, thereby achieving efficient light emission.

The highest hole mobility μₕ₃ and the highest electron mobility μₑ₃ among all the materials contained in the organic layer may satisfy the relation of 0.01<μₑ₃/μₕ₃<100. With the organic layer having higher bipolarity, the organic EL element can achieve even higher efficiency.

### REFERENCE SIGNS LIST

100A, 100B, 100C, 100D, 100E, 200A, 200B: organic EL panel
110, 210: substrate
120A, 120B, 120C, 120D, 120E, 220A, 220B: organic EL element
121: reflective electrode
122, 222: anode
123, 223: hole injection layer
124: hole transport layer
125A, 125B: first mixed light-emitting layer
126A: luminescent dopant layer
126B: first auxiliary dopant layer
126C: second auxiliary dopant layer
127A, 127B: second mixed light-emitting layer
128: electron transport layer
129, 229: electron injection layer
130A, 130B, 230: cathode
131: block layer
140A, 140B, 140C, 140D: light-emitting unit
226B: blue light-emitting layer
226G: green light-emitting layer
226R: red light-emitting layer
226Y: yellow light-emitting layer
231: intermediate layer

1: An organic electroluminescent element comprising, in the following order:
an anode;
a hole transport layer;
a first mixed light-emitting layer;
a luminescent dopant layer;
a second mixed light-emitting layer;
an electron transport layer; and
a cathode,
the first mixed light-emitting layer containing a first luminescent host material and a first luminescent dopant material,
the second mixed light-emitting layer containing a second luminescent host material and a second luminescent dopant material,
the luminescent dopant layer consisting essentially only of a third luminescent dopant material and being thinner than the first mixed light-emitting layer and the second mixed light-emitting layer.

2: The organic electroluminescent element according to claim 1,
wherein the luminescent dopant layer has a thickness of 1 nm or smaller.

3: The organic electroluminescent element according to claim 1,
wherein the highest hole mobility phi and the highest electron mobility μₑ₁ among all the materials contained in the first mixed light-emitting layer satisfy the relation of 1<μₑ₁/μₕ₁<1000.

4: The organic electroluminescent element according to claim 1,
wherein the highest hole mobility μₕ₂ and the highest electron mobility μₑ₂ among all the materials contained in the second mixed light-emitting layer satisfy the relation of 1<μₕ₂/μₑ₂<1000.

5: The organic electroluminescent element according to claim 1,
wherein the third luminescent dopant material has a peak emission at a longer wavelength than the first luminescent dopant material and the second luminescent dopant material.

6: The organic electroluminescent element according to claim 1, further comprising at least one of
a first auxiliary dopant layer that is disposed between the hole transport layer and the first mixed light-emitting layer and is consisting essentially only of a fourth luminescent dopant material, and
a second auxiliary dopant layer that is disposed between the second mixed light-emitting layer and the electron transport layer and is consisting essentially only of a fifth luminescent dopant material.

7: The organic electroluminescent element according to claim 6,
wherein the first auxiliary dopant layer or second auxiliary dopant layer has a thickness of 1 nm or smaller.

8: The organic electroluminescent element according to claim 6,
wherein the fourth luminescent dopant material has a light emission spectrum whose peak emission wavelength is within 20 nm from the peak emission wavelength of the first luminescent dopant material, and
the fifth luminescent dopant material has a light emission spectrum whose peak emission wavelength is within 20 nm from the peak emission wavelength of the second luminescent dopant material.

9: The organic electroluminescent element according to claim 1, further comprising
an organic layer disposed between the first mixed light-emitting layer and the luminescent dopant layer or between the luminescent dopant layer and the second mixed light-emitting layer.

10: The organic electroluminescent element according to claim 9,
wherein the organic layer has a thickness of 10 nm or smaller.

11: The organic electroluminescent element according to claim 9,
wherein the highest hole mobility μₕ₃ and the highest electron mobility μₑ₃ among all the materials contained in the organic layer satisfy the relation of 0.01<μₑ₃/μₕ₃<100.

12: An organic electroluminescent panel comprising:
a substrate; and
the organic electroluminescent element according to claim 1 disposed on the substrate.

13: The organic electroluminescent element according to claim 1,
wherein the luminescent dopant layer has an island shape.

14: The organic electroluminescent element according to claim 13,
wherein the luminescent dopant layer is disposed only at an interface between the first mixed light-emitting layer and the second mixed light-emitting layer.

15: The organic electroluminescent element according to claim 5,
wherein the first and second luminescent dopant materials are materials emitting blue light and green light, and the third luminescent dopant material is a material emitting red light.
